(19) United States
(12) Patent Application Publication
(10) Pub. No.: US 2012/0307473 A1
(43) Pub. Date: Dec. 6, 2012

(54) ELECTRONIC DEVICE WITH HIDDEN INTERFACE

(75) Inventor: WEN-CHIN HUNG, Tu-Cheng (TW)

(73) Assignee: HON HAI PRECISION INDUSTRY CO., LTD., Tu-Cheng (TW)

(21) Appl. No.: 13/241,172

(22) Filed: Sep. 22, 2011

(30) Foreign Application Priority Data
Jun. 2, 2011 (TW) 100119471

(51) Int. Cl. H05K 7/16

(52) U.S. Cl. 361/807

(57) ABSTRACT

An electronic device includes two chambers and two interface bodies. Each of the two interface bodies is rotatably connected to one of the two chambers, and is capable of being extended out of the chamber or received in the chamber under an external force. Each interface body includes a receiving part and an interface. The interface is received in the receiving part and connected to a main board of the electronic device.

### BACKGROUND

1. Technical Field

The present disclosure relates to an electronic device with hidden interfaces.

2. Description of Related Art

Many electronic devices include a number of interfaces for connection to peripheral devices. However, too many interfaces take up precious limited space on the exterior of the electronic device and can also be unsightly.

### BRIEF DESCRIPTION OF THE DRAWINGS

The components of the drawings are not necessarily drawn to scale, the emphasis instead being placed upon clearly illustrating the principles of the present disclosure. Moreover, in the drawings, like reference numerals designate corresponding parts throughout several views.

FIG. 1 is an isometric view of an electronic device with covered chambers, in accordance with an exemplary embodiment.

FIG. 2 is similar to FIG. 1, but showing the electronic device with the chambers uncovered and interface bodies extending out the chambers.

FIG. 3 is an exploded view of the electronic device of FIG. 1.

### DETAILED DESCRIPTION

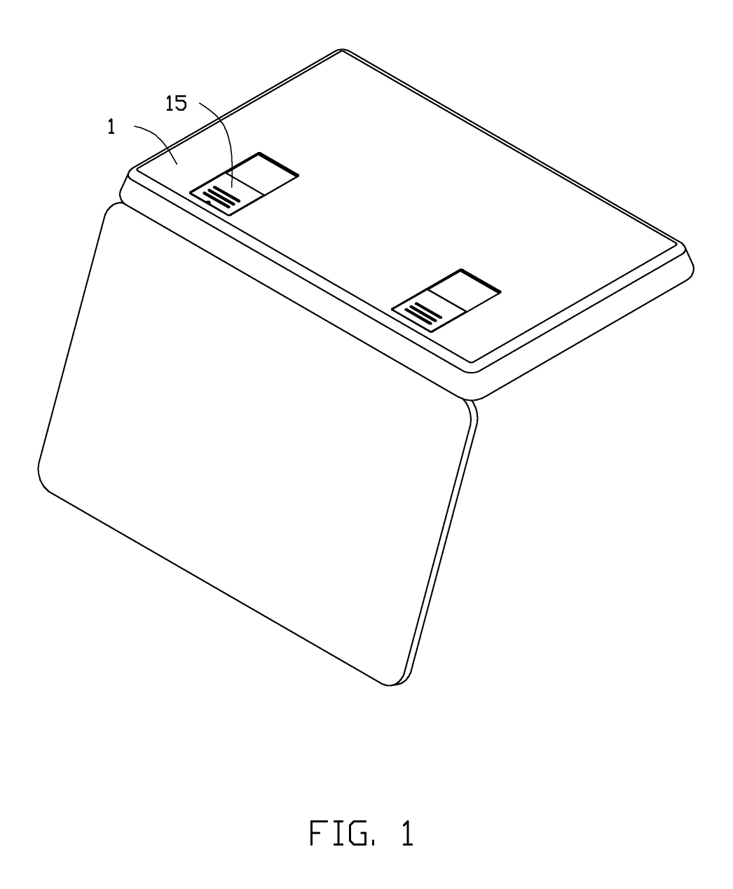

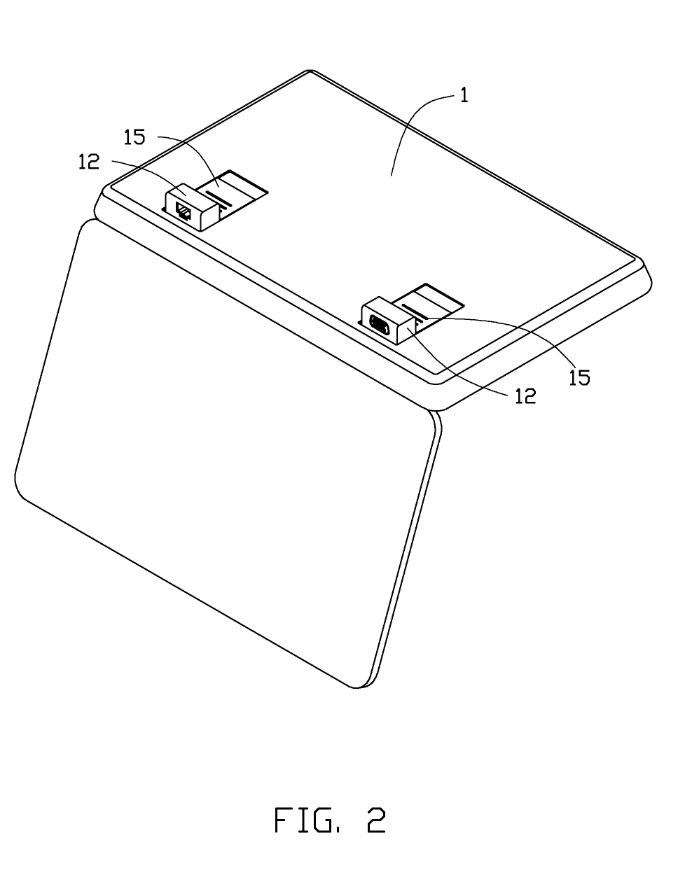

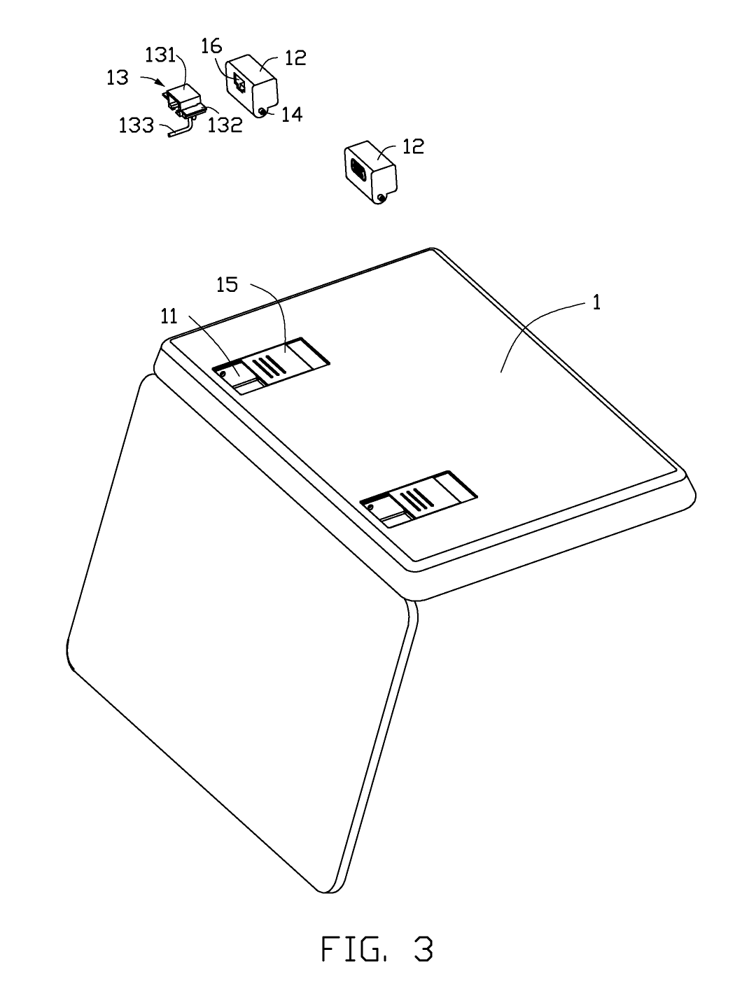

Referring to FIGS. 1-3, an electronic device 1 includes at least one interface body 12. Each interface body 12 is rotatably connected to a chamber 11. The at least one interface body 12 is extended out of the chamber 11 or received in the corresponding chamber 11. In this exemplary embodiment, for ease of description, only two chambers 11 and two interface bodies 12 are described, but there may be more or less than two of each. The electronic device 1 is a notebook computer. The chambers 11 and the interface bodies 12 are positioned in the bottom of the electronic device 1. The interface bodies 12 may also be used to adjust the height or inclination of the electronic device 1.

Each interface body 12 includes a receiving part 16 and an interface 13. The interface 13 is received in the receiving part 16. The interface 13 includes a connector 131, an interface circuit 132, and a wire 133. The connector 131, connected to the interface circuit 132, is for connecting to a peripheral device (not shown). The wire 133, connected to the interface circuit 132, is for connecting the interface circuit 132 to a main board (not shown) of the electronic device 1.

Two sides of each interface body 12 include a pivot portion 14 respectively. Each chamber 11 includes two pivot holes 17 that engage with the pivot portion 14 of two sides of the interface body 12 respectively to connect the interface body 12 to the chamber 11 rotatably. The interface body 12 is rotated to be extended out or received in the chamber 11.

In this exemplary embodiment, a cover 15 is provided for each chamber 11. Each cover 15 is slidably connected to the electronic device 1. When the interface bodies 12 are received in the chambers 11, the covers 15 are slid to cover the chambers 11. When the interface bodies 12 are in use, the covers 15 are slid to uncover the chambers 11.

Although, the present disclosure has been specifically described on the basis of preferred embodiments, the disclosure is not to be construed as being limited thereto. Various changes or modifications may be made to the embodiment without departing from the scope and spirit of the disclosure.

What is claimed is:

1. An electronic device comprising:
at least one chamber;
at least one interface body, each of the at least one interface body being rotatably connected to a corresponding one of the at least one chamber, and capable of being extended out of the corresponding chamber or received in the corresponding chamber, each of the at least one interface body comprising:
a receiving part, and
an interface being received in the receiving part and connected to a main board of the electronic device.

2. The electronic device as described in claim 1, wherein each of the at least one chamber comprises a cover, when each of the at least one interface body is received in the corresponding one of the at least one chamber, the cover is operable to cover the chamber, and the cover is operable to uncover the chamber when the interface body is to be extended out of the chamber.

3. The electronic device as described in claim 1, wherein two sides of each of the at least one interface body each comprise an pivot portion, each of the at least one chamber comprises two pivot holes that engage with the pivot portions of two side of the interface body respectively to connect the interface body to the chamber rotatably.

4. The electronic device as described in claim 1, wherein the number of the at least one chamber is two, and the number of the at least one interface body is two.

5. The electronic device as described in claim 4, wherein the two chambers are positioned in a bottom of the electronic device.

6. The electronic device as described in claim 5, wherein each cover is slidably connected to the corresponding chamber.

7. The electronic device as described in claim 6, wherein each interface body is operable to adjust the height or inclination of the electronic device when the interface body is extended out of the corresponding chamber.

8. The electronic device as described in claim 1, wherein the at least one chamber is positioned in a bottom of the electronic device, and each interface body is operable to adjust the height or inclination of the electronic device when the interface body is extended out of the corresponding chamber.
